(19) United States
(12) Patent Application Publication
(10) Pub. No.: US 2016/0023941 A1
(43) Pub. Date: Jan. 28, 2016

(54) COATING FOR GLASS WITH IMPROVED SCRATCH/WEAR RESISTANCE AND OLEOPHOBIC PROPERTIES

(71) Applicant: Intevac, Inc., Santa Clara, CA (US)

(72) Inventors: David Ward Brown, Pleasanton, CA (US); Charles Liu, Los Altos, CA (US); Jun Xie, San Jose, CA (US)

(21) Appl. No.: 14/805,418

(22) Filed: Jul. 21, 2015

Related U.S. Application Data
(60) Provisional application No. 62/027,745, filed on Jul. 22, 2014.
(60) Provisional application No. 62/033,099, filed on Aug. 4, 2014.

(51) Int. Cl. C03C 17/34; C23C 14/00; B08B 17/06; C23C 14/34

(52) U.S. Cl. CPC C03C 17/3441; C23C 14/34; C23C 14/0036; C03C 17/3435; C03C 17/3482; B08B 17/065; C03C 2217/734; C03C 2218/155; C03C 2217/78

(57) ABSTRACT

A protective coating on a front surface of a glass, by forming a diamond-like coating over the front surface of the glass; performing passive sputtering to form a protective layer directly on the diamond-like coating; performing reactive sputtering to form an adhesion layer directly on the protective layer; forming an anti-finger print layer directly over the adhesion layer.

### CROSS-REFERENCE TO RELATED APPLICATIONS

This application claims the benefit of priority from U.S. Provisional Patent Application Ser. No. 62/027,745, filed on Jul. 22, 2014, and from U.S. Provisional Patent Application Ser. No. 62/033,099, filed on Aug. 4, 2014, the entire disclosures of which are relied upon and incorporated herein by reference.

### BACKGROUND

1. Field

This disclosure relates to glass coating that improves scratch resistance and hydrophobic/oleophobic properties for use in, for example, touch screen displays.

2. Related Arts

Standard glass is susceptible to scratching and finger print marks, which present challenges for cover glass used in, e.g., touch screens of mobile devices. Various coatings have been developed for resisting scratching and provide oleophobic property to avoid or reduce finger printing.

Oleophobic coatings (also referred to as anti-fingerprint coatings, AFC) are known to provide oil-repelling properties to glass substrates, such that fingerprints do not adhere well and are easily wiped off. To produce a long lasting oleophobic coating that doesn't wear off easily, the coating process is performed by deposition of a SiO2 adhesion layer followed by deposition of an AFC coating. Deposition at atmosphere without SiO2 can also be performed, but the coating does not perform as long in wear tests (rubbing with steel wool or cheese cloth as examples).

A diamond-like coating, generally referred to as DLC, is known to significantly improve scratch resistance of glass substrates. However DLC is not sufficiently oleophobic for many applications on glass.

To provide both properties of scratch resistance and oleophpbic, it has been suggested to deposit DLC over the glass and an AFC over the DLC. However, AFC, such as FAS (fluoroalkylsilane), does not adhere well to a DLC film. Therefore, it has been suggested to use an oxide layer between the DLC and AFC, just as is done when applying AFC directly onto glass.

The application of oleophobic coatings on DLC coated glass was found to damage the DLC, effectively eliminating the expected scratch resistance. That is, taking a DLC coated substrate and subjecting it to standard AFC process, involving plasma clean and SiO2 adhesion layer deposition, damages the DLC coating. Thus, it appears that AF coating is incompatible with DLC coating such that the glass can be either protected from scratches or protected from finger prints, but not both.

3. Problem to be solved

It is desirable to obtain an improved AFC coating formed over a DLC film, such that the adhesion of the AFC is superior to prior art, so that the AFC oleophobic properties last a long time and resist rubbing.

### SUMMARY

The following summary is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

A nonobvious modification of the oleophobic deposition process was found, that not only preserved the DLC but also improved overall scratch resistance and durability of the oleophobic property.

According to one embodiment, a glass substrate was coated with a DLC film. Then a film of silicon was formed over the DLC, followed by a film of silicon dioxide formed over the silicon film. Then an AFC layer was formed over the silicon dioxide.

Aspects of the invention provide a glass for use on an electronic display screen, comprising: a glass substrate; a diamond-like coating over a front surface of the glass; an intermediate coating comprising a first layer formed directly on the diamond-like coating and containing silicon, and a second layer formed directly on the first layer and containing silicon and at least one of oxygen and nitrogen; and, an anti-fingerprint coating provided directly on the second layer.

Other aspects provide a method for forming a protective coating on a front surface of a glass, comprising: forming a diamond-like coating over the front surface of the glass; performing passive sputtering to form a protective layer directly on the diamond-like coating; performing reactive sputtering to form an adhesion layer directly on the protective layer; and, forming an anti-finger print layer directly over the adhesion layer.

Further aspects provide a method for forming a protective coating on a front surface of a glass, comprising: forming a diamond-like coating over the front surface of the glass; performing reactive sputtering to form a silicon oxynitride layer directly on the diamond like coating; and, forming an anti-finger print layer directly over the silicon oxynitride layer.

Other aspects and features of the invention would be apparent from the detailed description, which is made with reference to the following drawings. It should be appreciated that the detailed description and the drawings provides various non-limiting examples of various embodiments of the invention, which is defined by the appended claims.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 is a cross-section schematic illustrating an embodiment of the invention.

FIG. 2 is a cross-section schematic illustrating a second embodiment of the invention.

FIG. 3 is a cross-section schematic illustrating a third embodiment of the invention.

FIG. 4 is a cross-section schematic illustrating a fourth embodiment of the invention.

FIG. 5 is a cross-section schematic illustrating a fifth embodiment of the invention.

FIG. 6 is a schematic illustrating a hydrogenation process according to an embodiment of the invention.

FIG. 7 is a schematic illustrating a hydrogenation process according to a second embodiment of the invention.

FIG. 8 is a plot of the reflectance of the ARC, with or without an anti-scratch DLC top layer, according to an embodiment of the invention.

FIG. 9 is a schematic illustrating a processing system according to an embodiment of the invention.

### DETAILED DESCRIPTION

Embodiments disclosed herein were developed in order to provide improved adhesion properties of the AFC over a DLC layer, so as to both maintain the scratch resistant properties of the DLC layer, while improving the lasting of the oleophobic properties of the AFC film.

Tests of the oleophobic property of oil contact angle as a function of time during wear tests (rub cycles with steel wool) revealed unexpectedly that the contact angle held up longer on glass with AFC coated according to embodiments of the invention than for samples wherein the AFC was deposited using conventional oxide layer. An AF coating over glass produced using the standard process resulted is resistance to 2500 rubs at 110⁰ contact angle. (The contact angle is the exit angle of the beading oil drop). Conversely, the AF coating deposited over DLC coating using embodiments of the invention withstood over 5000 rubs.

Embodiments of the invention use DLC film coated over glass and an AFC film over the DLC film. A multi-layer intermediate film is interposed between the DLC and the AFC films. The multi-layer film may or may not include an oxide film. Also, an anti-reflective coating (ARC) film may be interposed between the glass and the DLC. The ARC may also be multi-layered.

The following are embodiments of the invention comprising DLC coated glass with an oleophobic coating. The entire coating is oleophobic and more scratch resistant than DLC or the oleophobic coating alone. The oleophobic property as measured with contact angle lasts longer in steel wool wear tests.

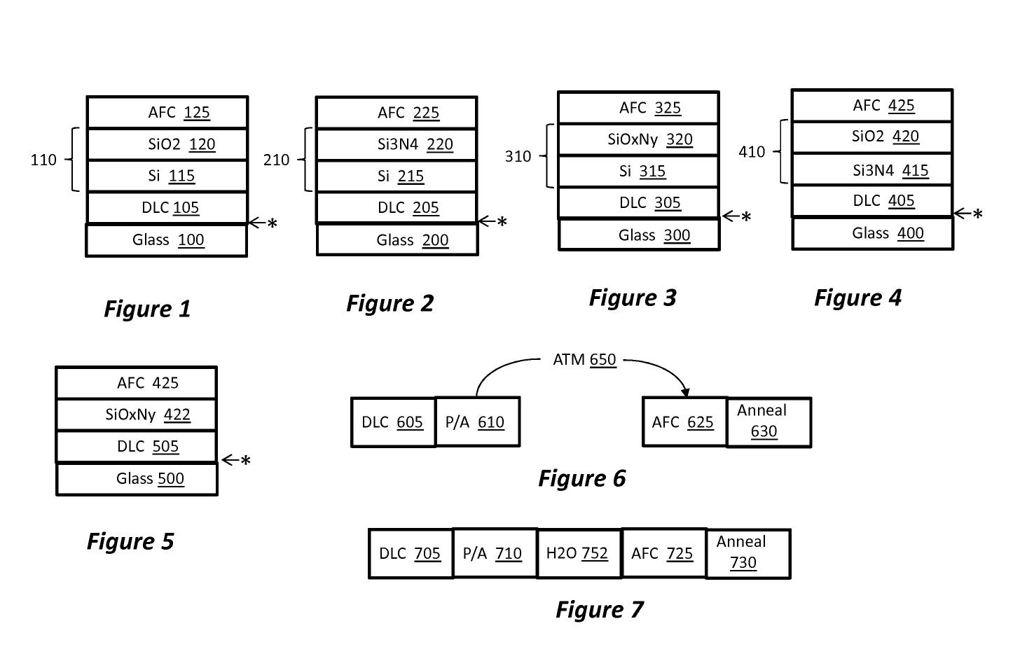

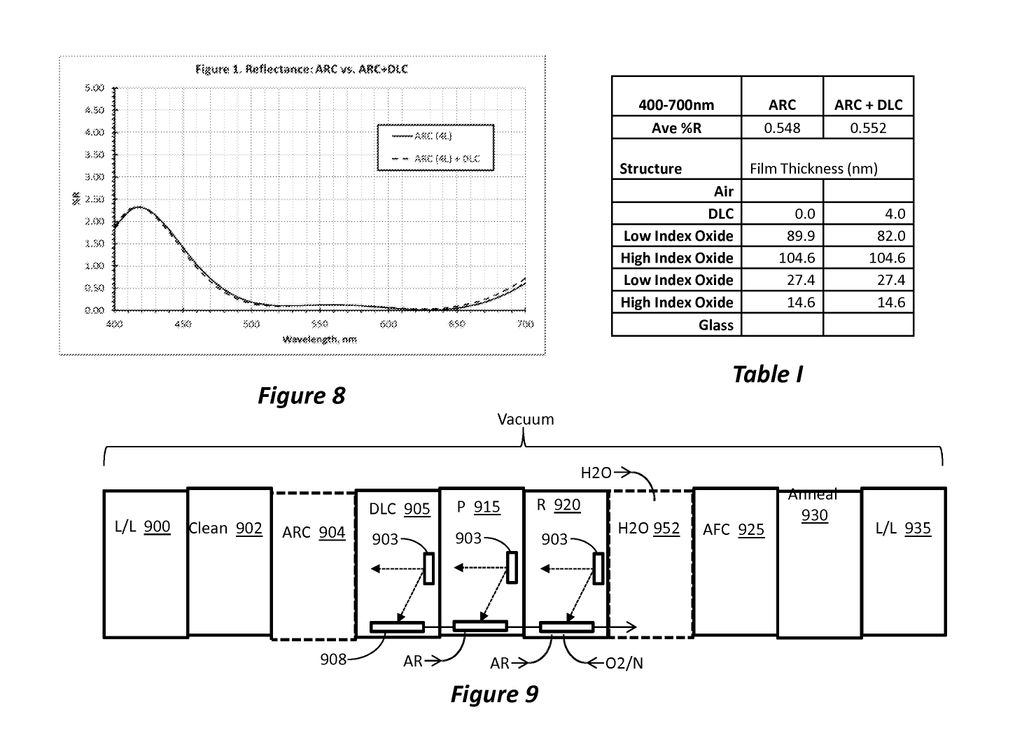

FIG. 1 is a cross-section schematic illustrating an embodiment of the invention. In FIG. 1, a DLC layer 105 is formed over glass substrate 100. The glass 100 may be a treated glass, such as, e.g., Gorilla® glass available from Corning®. Additionally, while not shown in FIG. 1, an ARC layer may be formed between the DLC and the glass. Therefore, in the context of this disclosure, the term A formed over B covers both situations where A is formed directly over B or A is formed on an intermediate layer that is between A and B.

In the embodiment of FIG. 1, a protective/adhesive multi-layer coating 110 is provided over the DLC 105. The multi-layer coating 110 functions, among others, to protect the DLC 105 and to enhance adhesion of the AFC 125. It was also discovered unexpectedly that the multi-layer coating 110 enhances the oleophobic performance of the AFC 125. The multi-layer coating 110 of FIG. 1 comprises a silicon protective layer 115 formed directly on and in contact with the DLC 105 and a silicon-oxide adhesion layer 120 formed directly on and in contact with the silicon layer 115. The AFC 125 is formed directly on and in contact with the silicon oxide layer 120.

In one embodiment the protective/adhesive multi-layer coating 110 is formed using PVD sputtering. In one embodiment the sputtering of both layers may be performed in a single chamber, while in another embodiment the layers are formed in two consecutive chambers. The silicon layer is formed using a silicon target and argon gas to ignite and maintain plasma. In one embodiment the sputtering is performed such that no plasma contacts the substrate and only particle sputtered at an acute angle to the plane of the silicon target are allowed to reach the substrate. Particles exiting at an angle perpendicularly to the plane of the target are prevented from reaching the substrate.

The sputtering of the silicon oxide layer 120 is performed using a silicon target and argon gas for sustaining the plasma, and oxide gas to react with the silicon particles. Thus, while the sputtering of the silicon layer is referred to as passive sputtering (i.e., only the material from the target is deposited on the substrate), the sputtering of the silicon oxide layer is referred to as reactive sputtering (i.e., a second species is reacting with the material from the target before it lands on the substrate). That is, in this particular example, the first layer is formed using passive sputtering process, while the second layer is formed using reactive sputtering process.

As a result of the process described, the DLC is protected by a layer of silicon, while the AFC layer adheres well to the silicon oxide layer. The silicon layer in this embodiment is formed to be very thin, so as to remain transparent. Specifically, the silicon layer is formed to about 5-10 Angstrom, or more specifically, 5-7 Angstrom. The silicon oxide may be formed to be thicker than the silicon layer. In this example, the silicon oxide layer is formed to be about 15-35 Angstrom or, more specifically, 20-30 Angstrom.

In one example, the transition from silicon to silicon oxide is graduated. This may be done by using a single chamber to form both layers. For example, a sputtering chamber with silicon target may be used, initially injecting only argon gas. When the silicon layer has reached a desired thickness, a flow of oxygen is introduced into the chamber and is gradually increased, such that the deposition is transitioned from pure silicon to silicon oxide, e.g., SiO2.

In another example, a boundary abrupt transition is provided between the silicon layer and the silicon oxide layer. This may be done in a single sputtering chamber having a silicon target initially injecting only argon gas. When the silicon layer has reached a desired thickness, the sputtering process may be stopped, and then a second process may commence, adding a flow of oxygen at a desired rate, such that the deposition is of a second layer of silicon oxide. Alternatively, once the silicon layer reached the desired thickness, the substrate may be transferred to a second sputtering chamber having both argon and oxygen gas flow, so as to form the silicon oxide layer.

FIG. 2 illustrates another embodiment. In the embodiment of FIG. 2, the multi-layer coating 210 comprises a silicon layer 215 formed directly on and in contact with the DLC 205 and a silicon-nitride layer 220 formed directly on and in contact with the silicon layer 115. The AFC 225 is formed directly on and in contact with the silicon nitride layer 220.

In one embodiment the protective/adhesive multi-layer coating 210 is formed using PVD sputtering. In one embodiment the sputtering of both layers may be performed in a single chamber, while in another embodiment the layers are formed in two consecutive chambers. The silicon layer is formed using a silicon target and argon gas to ignite and maintain plasma. In one embodiment the sputtering is performed such that no plasma contacts the substrate and only particle sputtered at an acute angle to the plane of the silicon target are allowed to reach the substrate. Particles exiting at an angle perpendicularly to the plane of the target are prevented from reaching the substrate.

The sputtering of the silicon nitride layer 220 is performed using a silicon target and argon gas for sustaining the plasma, and nitride gas to react with the silicon particles. Thus, in this particular example, the first layer is formed using passive sputtering process, while the second layer is formed using reactive sputtering process.

As a result of the process described, the DLC is protected by a layer of silicon, while the AFC layer adheres well to the silicon nitride layer. The silicon layer in this embodiment is formed to be very thin, so as to remain transparent. Specifically, the silicon layer is formed to about 5-10 Angstrom, or more specifically, 5-7 Angstrom. The silicon nitride may be formed to be thicker than the silicon layer. In this example, the silicon nitride layer is formed to be about 15-35 Angstrom or, more specifically, 20-30 Angstrom.

As before, the two layers may be formed using one or two chambers, and having graduated or abrupt transition.

FIG. 3 illustrates yet another embodiment. In the embodiment of FIG. 3, the multi-layer coating 310 comprises a silicon layer 315 formed directly on and in contact with the DLC 305 and a silicon-oxynitride layer 320 formed directly on and in contact with the silicon layer 315. The AFC 325 is formed directly on and in contact with the silicon nitride layer 320.

In one embodiment the protective/adhesive multi-layer coating 310 is formed using PVD sputtering. In one embodiment the sputtering of both layers may be performed in a single chamber, while in another embodiment the layers are formed in two consecutive chambers. The silicon layer is formed using a silicon target and argon gas to ignite and maintain plasma. In one embodiment the sputtering is performed such that no plasma contacts the substrate and only particle sputtered at an acute angle to the plane of the silicon target are allowed to reach the substrate. Particles exiting at an angle perpendicularly to the plane of the target are prevented from reaching the substrate.

The sputtering of the silicon oxynitride layer 320 is performed using a silicon target and argon gas for sustaining the plasma, and oxygen and nitride gases to react with the silicon particles. Thus, in this particular example, the first layer is formed using passive sputtering process, while the second layer is formed using reactive sputtering process.

As a result of the process described, the DLC is protected by a layer of silicon, while the AFC layer adheres well to the silicon nitride layer. The silicon layer in this embodiment is formed to be very thin, so as to remain transparent. Specifically, the silicon layer is formed to about 5-10 Angstrom, or more specifically, 5-7 Angstrom. The silicon oxynitride may be formed to be thicker than the silicon layer. In this example, the silicon oxynitride layer is formed to be about 15-35 Angstrom or, more specifically, 20-30 Angstrom.

As before, the two layers may be formed using one or two chambers, and having graduated or abrupt transition.

According to a further embodiment, a silicon nitride layer is used to protect the DLC layer. Specifically, in the embodiment of FIG. 4, the multi-layer coating 410 comprises a silicon nitride layer 415 formed directly on and in contact with the DLC 405 and a silicon-oxide layer 420 is formed directly on and in contact with the silicon nitride layer 415. The AFC 425 is formed directly on and in contact with the silicon oxide layer 420.

In one embodiment the protective/adhesive multi-layer coating 410 is formed using PVD sputtering. In one embodiment the sputtering of both layers may be performed in a single chamber, while in another embodiment the layers are formed in two consecutive chambers. The silicon nitride layer 415 is formed using a silicon target and argon and nitrogen gases. The sputtering of the silicon oxide layer 420 is performed using a silicon target and argon and oxygen gases. In one embodiment the sputtering is performed such that no plasma contacts the substrate and only particle sputtered at an acute angle to the plane of the silicon target are allowed to reach the substrate. Particles exiting at an angle perpendicularly to the plane of the target are prevented from reaching the substrate. Thus, in this particular example, both the first and second layers are formed using reactive sputtering process.

As a result of the process described, the DLC is protected by a layer of silicon nitride, while the AFC layer adheres well to the silicon oxide layer. The silicon nitride layer in this embodiment is formed to be very thin, so as to remain transparent. Specifically, the silicon layer is formed to about 5-10 Angstrom, or more specifically, 5-7 Angstrom. The silicon oxide may be formed to be thicker than the silicon layer. In this example, the silicon oxide layer is formed to be about 15-35 Angstrom or, more specifically, 20-30 Angstrom.

As before, the two layers may be formed using one or two chambers, and having graduated or abrupt transition.

According to yet another embodiment, illustrated in FIG. 5, coating 510 comprises a single layer comprising silicon oxynitride layer 522 formed directly on and in contact with the DLC 505. The AFC 525 is formed directly on and in contact with the silicon oxynitride layer 522.

In one embodiment the protective/adhesive coating 522 is formed using PVD sputtering. In one embodiment the sputtering of the layer may be performed in a single chamber, using reactive sputtering. The silicon oxynitride layer 522 is formed using a silicon target with a flow of argon, oxygen and nitrogen gases. In one embodiment the sputtering is performed such that no plasma contacts the substrate and only particle sputtered at an acute angle to the plane of the silicon target are allowed to reach the substrate. Particles exiting at an angle perpendicularly to the plane of the target are prevented from reaching the substrate.

As a result of the process described, the DLC is protected by the addition of nitrogen during the silicon sputtering, while the AFC layer adheres well due to the addition of oxygen during sputtering. The silicon oxynitride layer in this embodiment is formed so as to remain transparent. The silicon oxynitride may be formed to be about 15-35 Angstrom or, more specifically, 20-30 Angstrom.

According to a further embodiments, the protective/adhesive coating is hydrogenated prior to forming the AFC layer, so as to add hydrogen to dangling bonds of the top of the adhesive layer. This has been found to enhance the bonding of the AFC molecules to the silicon oxide. This is especially true for the complex molecules of FAS. Then, after the AFC is formed, the substrate is dehydrated by, e.g., annealing it to remove the moisture and complete the bonding. That is, the chemical reaction forming the bonds generates water molecules, especially at the interface between the adhesive later and the FAS, that should be removed. In one simple example, the substrate is exposed to humid atmosphere after completing the formation of the protective/adhesive coating and prior to forming the AFC layer. However, according to another embodiment, the hydrogenation is controlled by using a steam chamber within the production system.

FIG. 6 illustrates an example of hydrogenation-dehydration using atmospheric environment. In this embodiment, the DLC is formed at step 605 in a sputtering chamber. In this respect, the chambers are represented schematically as blocks, so as not to clutter the description. After the DLC film is formed, the substrate is moved to forming the protective/adhesive layer 610. Here, while only a single chamber is illustrated, as noted above, the multi-layer protective/adhesive layer may be formed using two or more chambers. Once the formation of protection/adhesive layer 610, the substrate is removed from the system and is exposed to atmosphere. Depending on the humidity and temperature at the factory, the exposure time may vary. The substrate is then returned to the system and the AFC layer 625 is formed. The substrate is then moved into anneal chamber 630 for dehydration.

The purpose of hydrogenating the adhesive layer 110 is to enable the chemical reaction that causes the FAS molecule to bond to the adhesive layer. However, left uncontrolled, the complex structure of the FAS molecule may also form bonds with neighboring FAS molecule, rather than to the adhesive layer. This reduces the service life of the FAS as anti finger print layer. Therefore, according to the embodiment illustrated in FIG. 7, the hydrogenation process is controlled within a processing chamber. Specifically, a DLC layer is formed over the substrate in 705. Then any of the disclosed protective/adhesive layers 710 is formed over the DLC 705. At this stage, the substrate remains within the vacuum system and is transferred into a hydrogenation chamber 752. This chamber has controlled temperature and controlled steam environment. The temperature and steam level are controlled so as not to provide sufficient time for the FAS molecules to bond to each other, rather than to the protective/adhesive layers 710. Thereafter, the substrate continues into the FAS chamber 725 for forming the FAS over the protective/adhesive layers 710. Thereafter, the substrate is annealed in chamber 730 for dehydration.

According to further embodiments, to achieve the best anti-scratch performance, according to disclosed embodiments a diamond-like carbon (DLC) layer is deposited by PVD or CVD on top of an ARC film stack. In some specific embodiments, the deposited DLC layer is a hydrogenated amorphous carbon that is super-smooth and has very low friction coefficient, making it an ideal anti-scratch top coat. Furthermore, with minor optimization of the optical model, the DLC layer has little impact on the overall ARC performance due, in part, to its excellent optical properties, such as medium refractive index (n: LI<DLC<HI) and low extinction coefficient (k<0.3, little light absorption).

According to a first example, a multilayer anti-reflection coating (ARC) is deposited over the glass substrate. The ARC comprises alternating layers of low-index and high-index materials, to form a stack that reduce the reflectance to 1% or below, averaged across the visible spectral range (□=400-700 nm). The multilayer ARC stack culminates with a diamond-like carbon layer as its topmost layer facing the incident medium, typically air. The average reflectance of ARC+DLC is similar to that of ARC alone. The structure of one embodiment of the ARC+DLC stack is shown in Table 1. Also, FIG. 8 is a plot of the reflectance of the ARC, with or without an anti-scratch DLC top layer. As can be seen, the DLC layer hardly affects the reflectance properties in the visible spectrum.

Moreover, experimental data shows that the multilayer ARC with DLC as its top most layer (ARC+DLC) has superior mechanical properties, allowing it to survive scratch or wear or impact tests better than the corresponding multilayer ARC without DLC. For example, multilayer ARC with DLC as its topmost layer can withstand more repetitions and/or greater loading force in a scratch test stand than the corresponding ARC without DLC by a factor of 2 or more.

An experimental setup wherein a glass bead is pressed against the glass with a set force, and a reciprocal motion is generated for 10 cycles, has been used to test the scratch resistance of the DLC. The force is increased for consecutive ten cycles, until scratches are visible. In the case of bare glass, the force for scratchiness was 0.5 Newton. Conversely, for glass with ARC only, the force was only 0.1 Newton, showing that ARC scratches rather easily and cannot be used for mobile devices. On the other hand, glass coated with the film of this embodiment withstood 5 Newton, which is ten times the force withstood by bare glass.

In the above example, the diamond-like carbon is made of hydrogenated amorphous carbon (a-CHx, where 0<x<2) with or without additional elements such as Ar, N, O, F, B, Si, Al, etc. The diamond-like carbon top-coat has a refractive index (n) between 1.4-2.0 over the visible spectral range, in other words, higher than that of the low index material and lower than the high index material used in the corresponding ARC structure. The diamond-like carbon top-coat has an extinction coefficient (k) less than 0.3 over the visible spectral range, that is, near clear with very little light absorption. For good performance, the thickness of DLC layer is designed to be a fraction of that of the top-most low-index material, while the top most ARC layer's thickness is reduced by the same amount (See Table 1). Typically the DLC layer's thickness is designed to be less than 10 nm, which results in very little impact, if any, in the optical performance. On the other hand, the anti-scratch performance is proportional to the DLC coating thickness.

Stated another way, an aspect of the invention is a combination ARC and DLC coating, wherein the ARC consists of alternating layers of low-index film and high-index film, wherein a terminating layer of the ARC consists of a low index film, and a DLC layer formed directly on the terminating layer, wherein the DLC layer is configured to have an index of refraction higher than the low index film but lower than the high index film, and wherein the DLC layer is formed to have a fraction of a thickness of the terminating film.

According to some embodiments, an ARC stack is formed by depositing alternating layers of SiO2 and Nb2O5, with the top layer being SiO2. The stack is designed so that the thickness of each layer would provide the desired anti-reflecting properties for the stack. Then, the designed thickness of the top layer is reduced by an amount equal to the thickness of the desired DLC layer. The DLC layer thickness is generally selected as 2-10 nm. For best results, the thickness of the DLC layer should be maintained between 2.5-3.5 nm. In some embodiments, the DLC layer is deposited using sputtering while flowing argon and hydrogen gas into the sputtering chamber. The argon gas is used to maintain plasma and sputter the DLC atoms from the sputtering target, while the hydrogen gas is used to hydrogenate the DLC during the sputtering process. The sputtering target is carbon, e.g., graphite. In one embodiment, a facing targets sputtering source is used, which is beneficial for forming a hydrogenated amorphous DLC layer.

This ARC+DLC arrangement may be used in any of the disclosed embodiment, as is illustrated by the asterisk arrow in the Figures. Prior to forming the ARC layer, the glass may be treated by exposing the front surface of the glass to plasma of oxygen and argon gas. Also, in the context of this disclosure, the various layers are said to be formed over the front surface of the glass. The term “front” surface refers to the surface exterior to the device upon which the glass is attached to. That is, the front surface is the surface contacted by the user to activate various functions of the mobile device.

Aspects of the invention include a method for forming a protective coating on a front surface of a glass, by forming a diamond-like coating over the front surface of the glass; forming a protective layer directly on the diamond-like coating, the protective layer consisting of silicon; forming an adhesion layer directly on the protective layer, the adhesion layer consisting of silicon and at least one of oxygen and nitrogen; and forming an anti-finger print layer directly over the adhesion layer.

Aspects of the invention provide a system for fabrication a protective coating over glass substrates 908 (moving among the chambers as shown by the arrow), illustrated in FIG. 9, and comprising: an entry vacuum loadlock 900; a plasma cleaning chamber 902; a diamond-like coating sputtering chamber 905; a protective coating passive sputtering chamber 915, comprising a silicon sputtering target 903 and an argon gas supply; an adhesion layer reactive sputtering chamber 920 comprising a silicon sputtering target 903, an argon gas supply, and a reactive gas supply consisting at least one of oxygen and nitrogen; an anti fingerprint coating evaporation chamber 925; an annealing chamber 930; and an exit vacuum loadlock 935. The system may further comprise an anti-reflective coating deposition chamber 904 positioned between the plasma cleaning chamber and the diamond-like coating sputtering chamber. The system may further comprise a hydrogenation chamber 952 positioned between the reactive sputtering chamber 920 and the anti fingerprint coating evaporation chamber 925. As shown by the dotted-arrows in FIG. 9, the silicon target 903 is configured such that particle sputtered from the target at orthogonal angle to the surface of the target cannot reach the substrate; rather, only particle sputtered at an acute angle to the surface of the target reach the substrate.

While the invention has been described with reference to particular embodiments thereof, it is not limited to those embodiments. Specifically, various variations and modifications may be implemented by those of ordinary skill in the art without departing from the invention's spirit and scope, as defined by the appended claims.

1. A glass for use on an electronic display screen, comprising:
a glass substrate;
a diamond-like coating over a front surface of the glass;
an intermediate coating comprising a first layer formed directly on the diamond-like coating and containing silicon, and a second layer formed directly on the first layer and containing silicon and at least one of oxygen and nitrogen;
an anti-fingerprint coating provided directly on the second layer.

2. The glass of claim 1, wherein the first layer consists of silicon.

3. The glass of claim 2, wherein the second layer consists of silicon and oxygen.

4. The glass of claim 2, wherein the second layer consists of silicon and nitrogen.

5. The glass of claim 2, wherein the second layer consists of silicon, nitrogen and oxygen.

6. The glass of claim 1, wherein the first layer consists of silicon and nitrogen.

7. The glass of claim 6, wherein the second layer consists of silicon and oxygen.

8. The glass of claim 1, further comprising an anti-reflective coating formed between the front surface of the glass and the diamond like coating.

9. The glass of claim 8, wherein the anti-reflective coating comprises alternating layers of SiO2 and Nb2O5, with a terminating layer being SiO2, and wherein the diamond-like coating is formed directly on the terminating layer.

10. The glass of claim 8, wherein the anti-reflective coating consists of alternating layers of low-index film and high-index film, wherein a terminating layer of the anti-reflective coating consists of a low index film, and the diamond like coating is formed directly on the terminating layer, wherein the diamond like coating is configured to have an index of refraction higher than the low index film but lower than the high index film, and wherein the diamond like coating is formed to have a fraction of a thickness of the terminating film.

11. A method for providing protective coating on a front surface of a glass, comprising:
forming a diamond-like coating over the front surface of the glass;
performing passive sputtering to form a protective layer directly on the diamond-like coating;
performing reactive sputtering to form an adhesion layer directly on the protective layer;
forming an anti-finger print layer directly over the adhesion layer.

12. The method of claim 11, wherein the passive sputtering is performed using a target consisting of silicon.

13. The method of claim 12, wherein the reactive sputtering is performed using a target consisting of silicon while injecting at least one of oxygen and nitrogen gas.

14. The method of claim 11, further comprising hydrogenating the adhesion layer prior to forming the anti-finger print layer.

15. The method of claim 14, further comprising dehydrating an interface between the adhesion layer and the anti-finger print layer.

16. The method of claim 15, wherein dehydration comprises annealing the glass.

17. The method of claim 14, wherein hydrogenating comprises placing the glass in a chamber and injecting steam into the chamber.

18. The method of claim 17, wherein the steps of forming a diamond-like coating, hydrogenating, and forming an anti-finger printing coating is performed without removing the glass from a vacuum environment.

19. The method of claim 11, wherein the anti-finger print coating consists of fluoroalkylsilane.

20. The method of claim 11, further comprising forming an anti-reflective coating between the glass and the diamond-like coating.

21. The method of claim 20, wherein forming an anti-reflective coating comprises forming alternating layers of SiO2 and Nb2O5, with a terminating layer being SiO2, and wherein the diamond-like coating is formed directly on the terminating layer.

22. The method of claim 21, further comprising exposing the front surface of the glass to plasma of oxygen and argon gas prior to forming the anti-reflective coating.
